(19) United States
(12) Patent Application Publication
(10) Pub. No.: US 2011/0011448 A1
(43) Pub. Date: Jan. 20, 2011

(54) THIN FILM SOLAR CELL AND METHOD OF MANUFACTURING THE SAME

(75) Inventors: Mi-Hwa LIM, Seocheon-gun (KR); Bo-Hwan PARK, Seoul, (KR)

Correspondence Address: CANTOR COLBURN LLP, 20 Church Street, 22nd Floor, Hartford, CT, 06103, US

(73) Assignee: SAMSUNG ELECTRONICS CO., LTD., Suwon-si, (KR)

(21) Appl. No.: 12/647,829

(22) Filed: Dec. 28, 2009

(30) Foreign Application Priority Data
Jul. 17, 2009 (KR) 10-2009-0065611

(51) Int. Cl. H01L 31/00; H01L 31/18

(52) U.S. Cl. 136/255; 136/256; 438/73; 257/E21.09; 257/E21.158; 257/E21.211

(57) ABSTRACT

A thin film solar cell includes a plurality of a unit solar cell each including an active area and a non-active area. Each unit solar cell further includes a first electrode, a first active layer disposed on the first electrode, an interlayer disposed on the first active layer, a second active layer disposed on the interlayer, and a second electrode disposed on the second active layer. The active area includes a first portion where the interlayer is disposed, and a second portion where the interlayer is not disposed.

This application claims priority to Korean Patent Application No. 10-2009-0065611 filed Jul. 17, 2009, and all the benefits accruing therefrom under §119, the entire contents of which are incorporated herein by reference.

### BACKGROUND OF THE INVENTION

1. Field of the Invention

This disclosure relates to a thin film solar cell and a method of manufacturing the same.

2. Description of the Related Art

A solar cell is a photoelectric conversion device transforming solar energy into electrical energy, and it has been drawing much attention as an infinite, but pollution-free, next-generation energy source.

A solar cell includes a p-type semiconductor and an n-type semiconductor. The solar cell produces electrical energy by transferring electrons and holes to the n-type and p-type semiconductors, respectively, and then collecting electrons and holes in each electrode, when electron-hole pairs (“EHPs”) are generated by solar light energy absorbed in a photoactive layer inside the semiconductors.

Solar cells may be divided into a crystalline solar cell and a thin film solar cell, according to structure of the solar cell. Since the thin film solar cell has a high light absorption coefficient in the visible light range compared to the crystalline solar cell, it is possible to manufacture a thin film type of solar cell and a wide area solar cell at a relatively low temperature, such as by using a glass substrate or a plastic substrate.

With the thin film solar cell, it is important to manufacture the solar cell to effectively absorb light coming from solar energy, and thus to increase its efficiency.

### BRIEF SUMMARY OF THE INVENTION

An exemplary embodiment of the invention provides a thin film solar cell having improved efficiency.

Another exemplary embodiment of the invention provides a method of manufacturing the thin film solar cell.

According to one exemplary embodiment of the invention, a thin film solar cell includes a plurality of a unit solar cell each with an active area and a non-active area. Each unit solar cell includes a first electrode, a first active layer disposed on the first electrode, an interlayer disposed on the first active layer, a second active layer disposed on the interlayer, and a second electrode disposed on the second active layer. The active area includes a first portion where the interlayer is disposed, and a second portion where the interlayer is not disposed.

The interlayer may include a plurality of an opening disposed in the active area of the unit solar cell. The non-active area may include, a first scribe line penetrating the first electrode, a second scribe line penetrating the first active layer and the interlayer, a third scribe line penetrating the first active layer, the interlayer, and the second active layer, and a fourth scribe line penetrating the first active layer, the interlayer, the second active layer, and the second electrode.

The interlayer may be formed in a shape of a plurality of an island. The non-active area may include a first scribe line penetrating the first electrode, a second scribe line penetrating the first active layer, the interlayer, and the second active layer, and a third scribe line penetrating the first active layer, the interlayer, the second active layer, and the second electrode.

The interlayer may include a selective light transmission material which allows light of first wavelength ranges to be transmitted therethrough, and reflects light of second wavelength ranges different from the first wavelength ranges.

The selective light transmission material may include at least one selected from the group consisting of a metal oxide, a semi-metal oxide, a semi-metal nitride, and a combination thereof.

The selective light transmission material may include at least one selected from the group consisting of zinc oxide, tungsten oxide, silicon oxide, silicon nitride, and a combination thereof.

The first active layer and the second active layer may respectively absorb light of different wavelength ranges.

The first active layer may include amorphous silicon, and the second active layer may include at least one selected from the group consisting of amorphous silicon, doped amorphous silicon, nanocrystalline silicon, microcrystalline silicon, and a combination thereof.

The thin film solar cell may further include a third active layer disposed between the first active layer and the interlayer, and/or between the second active layer and the interlayer. The third active layer includes doped amorphous silicon.

According to another exemplary embodiment of the invention, a method for manufacturing a thin film solar cell including a plurality of unit solar cells each including an active area and a non-active area, includes forming a first electrode on a substrate, forming a first active layer on the first electrode, forming an interlayer on the first active layer, forming a second active layer on the interlayer, and forming a second electrode on the second active layer. The interlayer is disposed in a first portion of the active area, and is not disposed in a second portion of the active area.

The forming an interlayer on the first active layer may include disposing the interlayer on the first active layer, and patterning the interlayer in the active area of the unit solar cell.

The interlayer may be patterned using a laser.

The method may further include patterning the first electrode disposed in the non-active area after the first electrode is formed, patterning the interlayer and the first active layer disposed in the non-active area after the interlayer is formed, and patterning the second active layer, the interlayer, and the first active layer disposed in the non-active area after the second active layer is formed. The patterning the interlayer disposed in the active area is performed during the patterning the interlayer and the first active layer disposed in the non-active area after the interlayer is formed.

The forming an interlayer may include depositing the interlayer on the first active layer in a shape of islands.

The interlayer may be formed by a thin film growth method.

The thin film growth method may include sputtering and chemical vapor deposition (“CVD”) methods.

### BRIEF DESCRIPTION OF THE DRAWINGS

The above and other advantages and features of the invention will become more apparent by describing in further detail exemplary embodiments thereof, with reference to the accompanying drawings, in which:

FIG. 1 is a top plan view of an exemplary embodiment of one unit solar cell of a thin film solar cell, according to the invention.

FIG. 2 is a cross-sectional view of the unit solar cell of FIG. 1, taken along line II-II.

FIG. 3 is a cross-sectional view of an exemplary embodiment of a stacked structure of the unit solar cell shown in FIGS. 1 and 2.

FIG. 4 is a cross-sectional view showing an exemplary embodiment of incident light within the solar cell in FIG. 3, according to the invention.

FIGS. 5A to 5F are cross-sectional views sequentially showing an exemplary embodiment of a process of manufacturing the unit solar cell of FIGS. 1 to 3.

FIG. 6 is a top plan view of another exemplary embodiment of one unit solar cell of a thin film solar cell, according to the invention.

FIG. 7 is a cross-sectional view of the unit solar cell of FIG. 6 taken along line VII-VII.

FIG. 8 is a cross-sectional view schematically showing an exemplary embodiment of incident light and electrical current flow within the unit solar cell of FIG. 7, according to the invention.

FIGS. 9A to 9F are cross-sectional views sequentially showing an exemplary embodiment of a process of manufacturing the unit solar cell of FIGS. 6 and 7.

### DETAILED DESCRIPTION OF THE INVENTION

Exemplary embodiments of the invention will hereinafter be described in detail referring to the following drawings, and can be easily performed by those who have common knowledge in the related field. However, these embodiments are only exemplary, and the invention is not limited thereto.

In the drawings, the thickness of layers, films, panels, areas, etc., are exaggerated for clarity. Like reference numerals designate like elements throughout the specification. It will be understood that when an element such as a layer, film, area, or substrate is referred to as being “on” another element, it can be directly on the other element or intervening elements may also be present. In contrast, when an element is referred to as being “directly on” another element, there are no intervening elements present. As used herein, connected may refer to elements being physically and/or electrically connected to each other. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower”, “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “upper” relative to other elements or features would then be oriented “lower” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

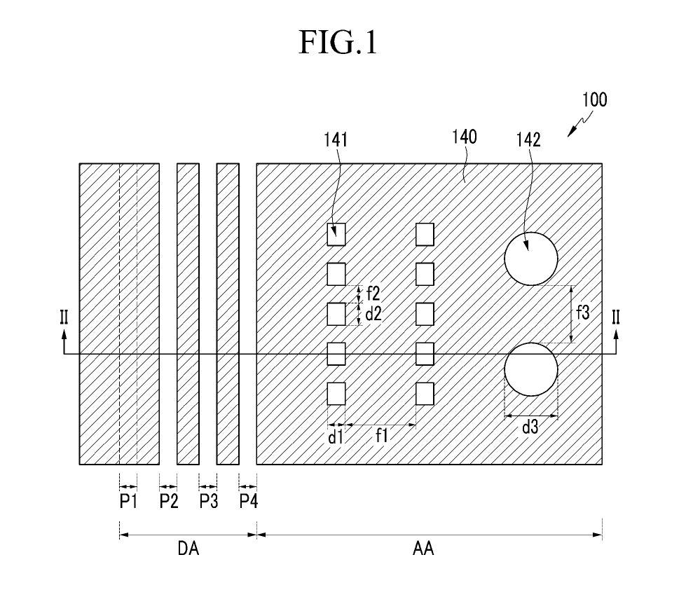

Referring to FIGS. 1 to 3, a thin film solar cell according to one exemplary embodiment, is described in detail.

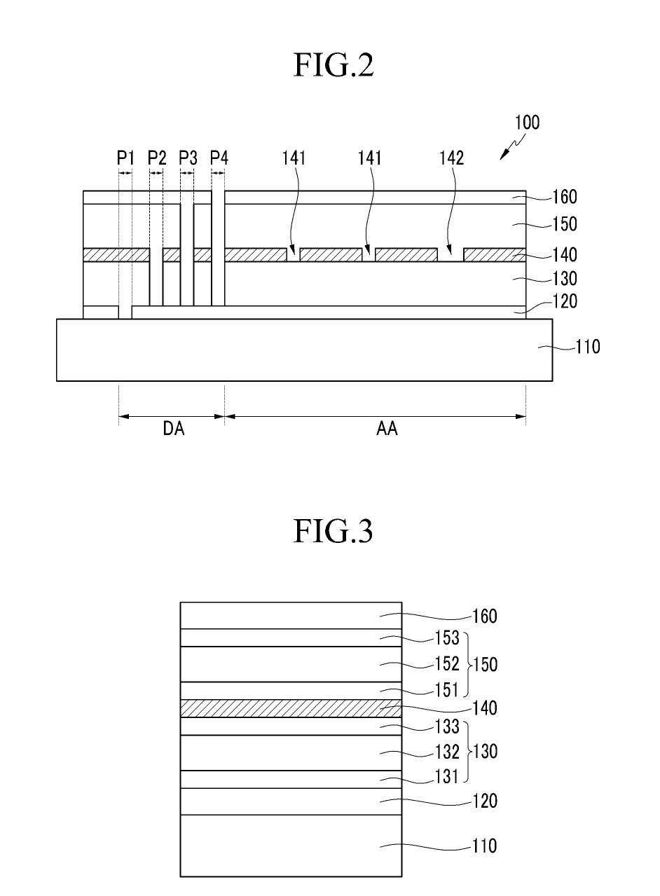

FIG. 1 is a top plan view of an exemplary embodiment of one unit solar cell of thin film solar cell, according to the invention, FIG. 2 is a cross-sectional view of the unit solar cell of FIG. 1 taken along line II-II, while FIG. 3 is a cross-sectional view of an exemplary embodiment of a stacked structure of the unit solar cell shown in FIGS. 1 and 2.

The thin film solar cell includes a plurality of a unit solar cell 100. The unit solar cells 100 are arrayed in a matrix form and are connected in series within the thin film solar cell.

Referring to FIGS. 1 and 2, each unit solar cell 100 of the thin film solar cell includes an active area (“AA”) and a non-active area (“DA”). The active area AA is an effective area of a unit solar cell, where solar energy is received and photoelectric current is generated, whereas the non-active area DA is an area of the unit solar cell where a plurality of scribe lines are disposed to separate adjacent unit solar cells from each other within the thin film solar cell.

Referring to FIGS. 1 to 3, a first electrode 120 is disposed directly on a substrate 110. The substrate 110 may include glass or plastic, and forms the lowermost layer of the unit solar cell 100. The first electrode 120 collectively include a plurality of portions, each portion of the first electrode 120 being a single unitary indivisible member of the unit solar cell 100 structure. The first electrode 120 may include a transparent conductive oxide (“TCO”). Non-limiting examples of the transparent conductive oxide include SnO₂:F (fluorine-doped tin oxide, “FTO”), ZnO:Al (aluminum-doped zinc oxide, “AZO”), ZnO:B (boron-doped zinc oxide), InSnO₂ (indium tin oxide, “ITO”), and the like.

The first electrode 120 may be texturized. Non-limiting examples of the texturing of a texturized first electrode 120, may include protrusions and depressions such as a pyramid shape, and/or pores such as a honeycomb structure.

A texturized substrate 110 may reduce reflection of incident light, and at the same time increase scattering of the incident light to thereby increase a path of light. The increased light path, may increase the amount of effective light absorbed into a thin film solar cell.

A first active layer 130 is disposed directly on the first electrode 120. Referring to FIG. 3, the first active layer 130 includes a first impurity doped layer 131, an intrinsic layer 132, and a second impurity doped layer 133. The first impurity doped layer 131 may include silicon doped with a p-type impurity. The second impurity doped layer 133 may include silicon doped with an n-type impurity.

The intrinsic layer 132 may include intrinsic amorphous silicon (intrinsic “a-Si”), and/or may include hydrogenated amorphous silicon (“a-Si:H”) to reduce defects. The intrinsic layer 132 absorbs light, and produces electrical charges such as electrons and holes. In an exemplary embodiment of the invention, the intrinsic layer 132 may absorb light of a short wavelength, ranging from about 300 nanometers (nm) to about 700 nm. The intrinsic layer 132 may have a thickness in a direction perpendicular to the substrate 110, ranging from about 200 nm to about 800 nm.

The first impurity doped layer 131 and the second impurity doped layer 133 may collectively form an internal electric field, to thereby separate the electrical charges generated in the intrinsic layer 132. The first impurity doped layer 131 may include a material having high electrical conductivity and a small light absorption coefficient, as a window material. The first impurity doped layer 131 and the second impurity doped layer 133 may each have a thickness in the direction perpendicular to the substrate 110, ranging from about 10 nm to about 50 nm, individually.

An interlayer 140 is disposed directly on the first active layer 130, and on the second impurity doped layer 133 of the first active layer 130. The interlayer 140 is disposed only in a portion of the active area AA. As illustrated in FIGS. 1 and 2, the active area AA includes a first area where the interlayer 140 is disposed, and a second (e.g., remaining) area where the interlayer 140 is not disposed. The interlayer 140 will be described later.

A second active layer 150 is disposed directly on the interlayer 140. Referring to FIG. 3, like the first active layer 130, the second active layer 150 includes a first impurity doped layer 151, an intrinsic layer 152 and a second impurity doped layer 153.

The intrinsic layer 152 of the second active layer 150 may absorb light of a wavelength range that is different from a wavelength range of the intrinsic layer 132 of the first active layer 130. The intrinsic layer 152 may absorb light of a long wavelength, ranging from about 500 nm to about 1200 nm. The second active layer 150 includes at least one material selected from the group consisting of amorphous silicon, doped amorphous silicon, nanocrystalline silicon, microcrystalline silicon, and a combination thereof. The doped amorphous silicon may be amorphous silicon-germanium (“a-SiGe”).

Of light that has entered an incident surface of the substrate 110 and that has traveled through the substrate 110, a first portion of the light of some wavelength ranges of the incident light may be absorbed by the first active layer 130, and a second portion of the light of some wavelength ranges may completely pass through the interlayer 140 and be absorbed by the second active layer 150. In one exemplary embodiment, a first portion of light of a short wavelength range of the incident light, may be absorbed by the first active layer 130 to thereby generate a photoelectric current, and a second portion of light of a long wavelength range of the incident light, may completely pass through the interlayer 140 and be absorbed by the second active layer 150 to thereby generate a photoelectric current.

A second electrode 160 is disposed directly on the second active layer 150, and forms an uppermost layer of the unit solar cell 100. The second electrode 160 may include at least one material selected from the group consisting of aluminum (Al), silver (Ag), and a combination thereof.

Referring again to FIGS. 1 and 2, a non-active area DA includes a plurality of a scribe line P1, P2, P3, and P4, which separate adjacent unit solar cells from each other within the thin film solar cell, and electrically connect the separated unit solar cells to each other, respectively. The plurality of the scribe line includes a first scribe line P1 for separating portions of the first electrode 120 from each other in a plan view of the unit solar cell 100, a second scribe line P2 penetrating completely through each of the first active layer 130 and the interlayer 140 in the direction perpendicular to the substrate 110, a third scribe line P3 penetrating completely through each of the first active layer 130, the interlayer 140, and the second active layer 150 in the direction perpendicular to the substrate 110, and a fourth scribe line P4 penetrating completely through each of the first active layer 130, the interlayer 140, the second active layer 150 and the second electrode 160 in the direction perpendicular to the substrate 110. Portions within each of the second scribe line P2, the third scribe line P3 and the fourth scribe line P4 disposed penetrating through the respective layers are aligned with each other, such that the second scribe line P2, the third scribe line P3 and the fourth scribe line P4 are each a continuous unitary member of the unit solar cell 100 as penetrating through the respective layers.

The first scribe line P1 is longitudinally extended in a first (e.g., vertical) direction, in a plan view of the unit solar cell 100. The second scribe line P2, the third scribe line P3 and the fourth scribe line P4 are each longitudinally extended in the first direction, in a plan view of the unit solar cell 100, and are each arranged parallel to the first scribe line P1. Each of the first scribe line P1, the second scribe line P2, the third scribe line P3 and the fourth scribe line P4 are longitudinally extended an entire dimension of the unit solar cell 100 in the first direction.

As described above, the unit solar cell 100 of the illustrated embodiment includes the interlayer 140 between the first active layer 130 and the second active layer 150. Disposed between the first active layer 130 and the second active layer 150, the interlayer 140 may serve as a buffer layer for reducing defects that may occur in the interface of the first active layer 130 and the second active layer 150 where different doping layers meet (e.g., contact) each other.

The interlayer 140 may include a selective light transmission material that allows light of some first wavelength ranges to pass therethrough, while reflecting light of some second wavelength ranges which may be different from the first wavelength ranges. Non-limiting examples of the selective light transmission material may include a metal oxide, e.g., zinc oxide or tungsten oxide, a semi-metal oxide, e.g., silicon oxide, a metal nitride, e.g., silicon nitride, and a combination thereof.

Where incident light enters and passes through the substrate 110, the interlayer 140 may reflect a portion of the incident light of a wavelength range absorbed by the first active layer 130, while transmitting a portion of the incident light of a wavelength range absorbed by the second active layer 150. In one exemplary embodiment, when the first active layer 130 absorbs light of a short wavelength and the second active layer 150 absorbs light of a long wavelength, the interlayer 140 may reflect the light of the short wavelength and allow the light of the long wavelength to pass therethrough.

With the selective light transmission, the first active layer 130 may use the reflected light returned to the first active layer by the interlayer 140, to thereby increase the amount of light absorption. Also, the thickness of the first active layer 130 may be minimized so as to maximize the gain of the light absorption by the first active layer 130 obtained from the light reflection of the interlayer 140. Therefore, photodegradation of the first active layer 130 occurring in proportion to the thickness, may also be decreased.

In the illustrated embodiment, the interlayer 140 is disposed only in a portion of the active area AA of a unit solar cell 100. As shown in FIGS. 1 and 2, the active area AA of the unit solar cell 100 includes a first portion where the interlayer 140 is disposed, and a second portion where the interlayer 140 is not disposed. The second portion where the interlayer 140 is not disposed excludes the first portion where the interlayer 140 is disposed.

Referring to FIGS. 1 and 2, the second portion of the active area AA of the unit solar cell 100, where the interlayer 140 is not disposed may include a first opening 141 and a second opening 142. The first and second openings 141 and 142 may be provided in plural within the unit solar cell 100, and may be arrayed with different sizes and shapes in the plan and/or cross-sectional view of the unit solar cell 100 structure. Each of the first and second openings 141 and 142 are an enclosed opening penetrating the interlayer 140 disposed in the active area AA, such that the interlayer 140 solely defines the enclosed first and second openings 141 and 142.

As discussed above, it is possible to increase the light absorption amount by including in the active area AA the first portion where the interlayer 140 is disposed, and the second portion where the interlayer 140 is not disposed (e.g., removed in a manufacturing process), such as at the openings 141 and 142.

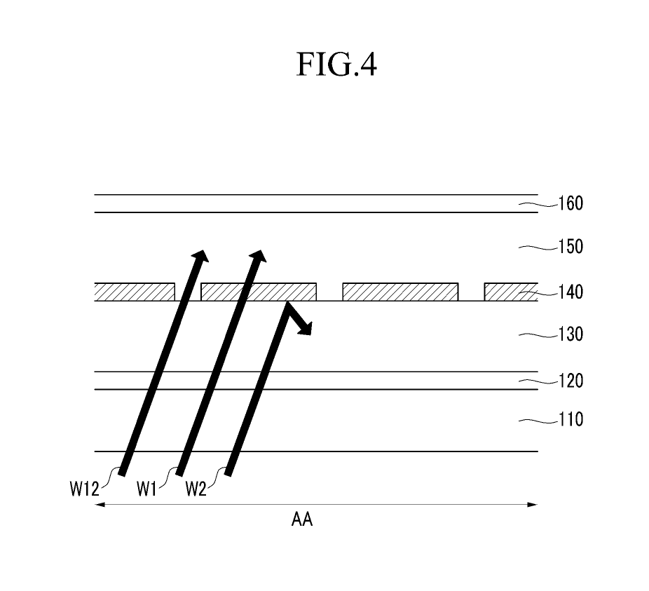

An increase of the light absorption amount by including the first portion and the second portion of the active area AA will be described with reference to FIG. 4.

FIG. 4 is a cross-sectional view schematically showing an exemplary embodiment of a path of travel of incident light in a thin film solar cell, in accordance with the invention.

Referring to FIG. 4, a first portion (“W1”) of the incident light entering and passing through the substrate 110 in an active area AA of the unit solar cell 100 passes completely through a thickness of the interlayer 140 and is subsequently absorbed by the second active layer 150, as shown by the arrow labeled “W1.” A second portion (“W2”) of the incident light is reflected by the interlayer 140 and returns to the first active layer 130, as shown by the arrow labeled “W2.” Since the second portion of the incident light W2 reflected by the interlayer 140 may be re-absorbed by the first active layer 130, the efficiency of the first active layer 130 may be increased.

A third portion (“W12”) of the incident light entering and passing through the substrate 110 may reach the second active layer 150 through the second portion of the active layer AA where the interlayer 140 is removed, that is, through the first and second openings 141 and 142. Thus, it is possible to reduce or effectively prevent the total amount of light reaching the second active layer 150 from being reduced by the interlayer 140.

According to the illustrated embodiment, the electrical current amounts of the first active layer 130 and the second active layer 150 are simultaneously controlled, and an efficiency of the unit solar cell 100 is improved by using the interlayer 140 to increase the efficiency of the first active layer 130, and at the same time, by removing a portion of the interlayer 140 to increase the amount of light reaching the second active layer 150.

In the illustrated embodiment, the first active layer 130 and the second active layer 150 are designed to have appropriate efficiency by controlling a planar area of the interlayer 140 and a planar dimension of the first and second openings 141 and 142. In one exemplary embodiment, referring to FIG. 1, the planar area of the interlayer 140 and the planar dimensions of the first and second openings 141 and 142 may be respectively designed in consideration of dimensions d1, d2, and d3 of the openings 141 and 142, and distances f1, f2, and f3 between adjacent first and second openings 141 and 142.

In the plan view of the unit solar cell 100 shown in FIG. 1, each of the first openings 141 is a discrete element which is separate from an adjacent first opening 141, and has a rectilinear, or square, shape, but the invention is not limited thereto. A plurality of the first opening 141 is linearly arranged in a direction, to collectively form a group of the first opening 141. FIG. 1 includes two groups of the first opening 141 linearly arranged in the first (e.g., vertical) direction in the active area AA, and includes five groups of the first opening 141 arranged in a second (e.g., horizontal) direction perpendicular to the first direction, but the invention is not limited thereto. While FIG. 1 shows a regular arrangement of the first openings 141, the openings in the interlayer 140 may be discontinuously or irregularly arranged.

Each of the first openings 141 has the dimension d1 in the horizontal direction, and the dimension d2 taken in the vertical direction. The distance f1 defines a spacing between edges of adjacent first openings 141 arranged in the horizontal direction, and the distance F2 defines a spacing between edges of adjacent first openings 141 arranged in the vertical direction.

In the plan view of the unit solar cell 100 shown in FIG. 1, each of the second openings 142 has a circular shape, but the invention is not limited thereto. A plurality of the second opening 142 is linearly arranged in a direction, to collectively form a group of the second opening 142. FIG. 1 includes one group of the second opening 142 linearly arranged in a vertical direction in the active area AA.

Each of the second openings 142 has the dimension d3, which is effectively the diameter of the second opening 142. The distance f3 defines a spacing between edges of adjacent second openings 142 which are arranged in the vertical direction.

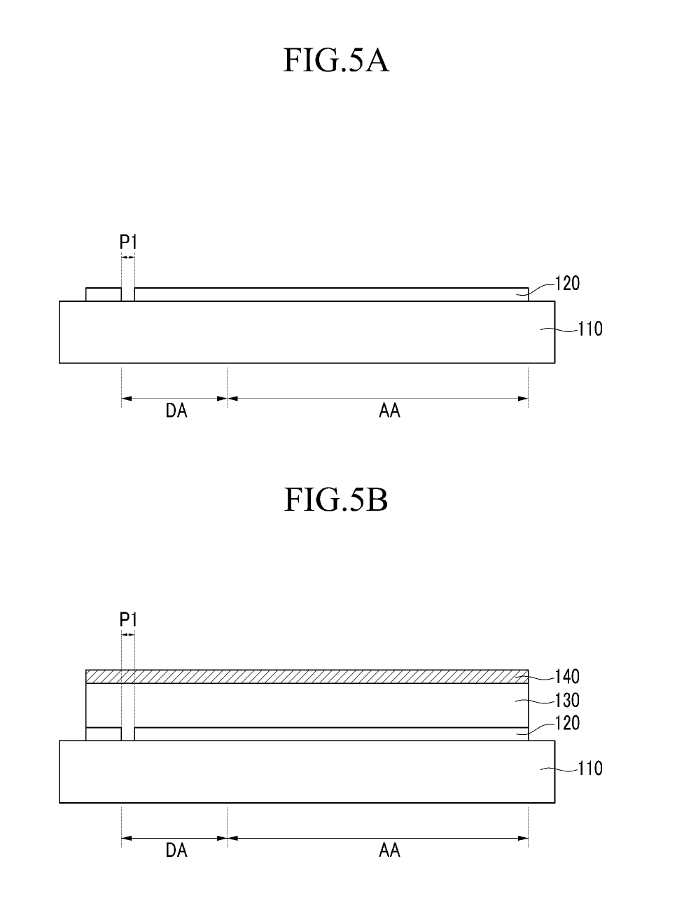

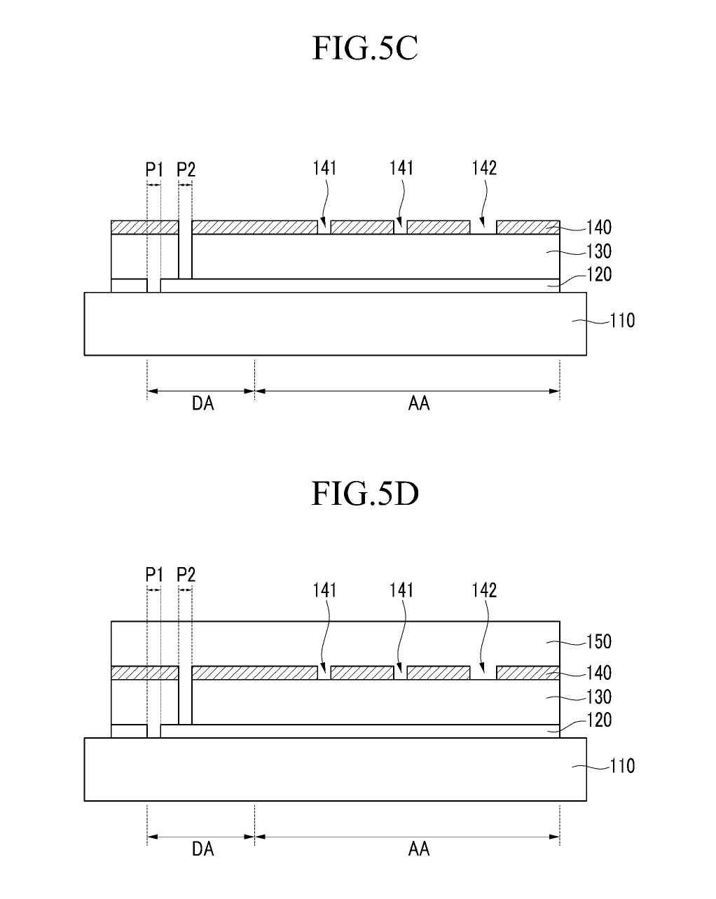

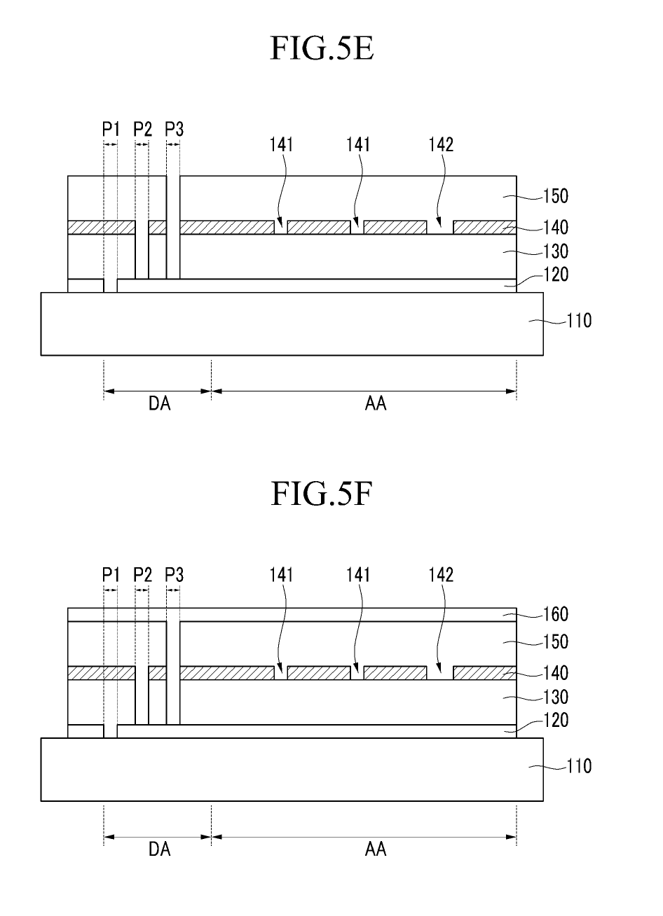

Hereafter, an exemplary embodiment of a method for manufacturing the unit solar cell 100 illustrated in FIGS. 1 to 3 will be described with reference to FIGS. 5A to 5F along with FIGS. 1 to 3.

FIGS. 5A to 5F are cross-sectional views sequentially showing an exemplary embodiment of a process of manufacturing a unit solar cell illustrated in FIGS. 1 to 3.

Referring to FIG. 5A, a first electrode 120 is formed directly on a substrate including a material such as glass. The first electrode 120 may be formed by depositing a transparent conductive oxide through a process such as sputtering.

Subsequently, the first electrode 120 is patterned using a scribing device, such as a neodymium-doped yttrium aluminium garnet (“Nd:YAG”) laser, to thereby form a first scribe line P1 in only a non-active area DA of the unit solar cell 100.

Referring to FIG. 5B, a first active layer 130 and an interlayer 140 are sequentially formed directly on the first electrode 120. As described above, the first active layer 130 includes a first impurity doped layer 131, an intrinsic layer 132, and a second impurity doped layer 133. The first impurity doped layer 131, the intrinsic layer 132, the second impurity doped layer 133, and the interlayer 140 may be sequentially formed on the first electrode 120 through a plasma enhanced chemical vapor deposition (“PECVD”) method.

Referring to FIG. 5C, the first active layer 130 and the interlayer 140 are patterned using a scribing device such as a Nd:YAG laser, to thereby form a second scribe line P2 in the non-active area DA and form a plurality of first and second openings 141 and 142 in an active area AA of the unit solar cell 100. In an exemplary embodiment, a laser used to perform patterning on the first active layer 130 and the interlayer 140 of a different wavelength from the wavelength of the laser used to perform patterning on the first electrode 120, may be used so as to not damage the first electrode 120. The first active layer 130 and the interlayer 140 may be simultaneously patterned using the scribing device.

As described above, since the step of forming the first and openings 141 and 142 in the interlayer 140 of the active area AA, may be performed during the formation of the second scribe line P2 of the non-active area DA, an additional process in the method of manufacturing a unit solar cell is not required.

Referring to FIG. 5D, a second active layer 150 is formed directly on the interlayer 140. As described above, the second active layer 150 includes a first impurity doped layer 151, an intrinsic layer 152, and a second impurity doped layer 153. The first impurity doped layer 151, the intrinsic layer 152, and the second impurity doped layer 153 may be sequentially formed through a plasma enhanced chemical vapor deposition (“PECVD”) method.

Referring to FIG. 5E, the second active layer 150, the interlayer 140, and the first active layer 130 are patterned using a scribing device such as a Nd:YAG laser to thereby form a third scribe line P3 in the non-active area DA. The second active layer 150, the interlayer 140, and the first active layer 130 may be simultaneously patterned using the scribing device.

Referring to FIG. 5F, a second electrode 160 is formed directly on the second active layer 150. The second electrode 160 may be formed by sputtering an opaque metal.

Referring to FIG. 2, the second electrode 160, the second active layer 150, the interlayer 140, and the first active layer 130 are patterned using a scribing device such as a Nd:YAG laser to thereby form a fourth scribe line P4 in the non-active area DA. The second electrode 160, the second active layer 150, the interlayer 140, and the first active layer 130 may be simultaneously patterned using the scribing device.

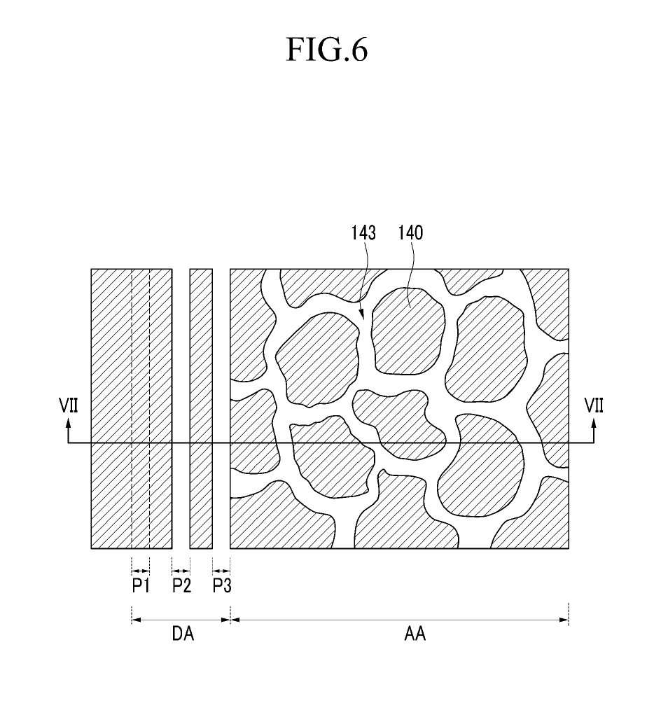

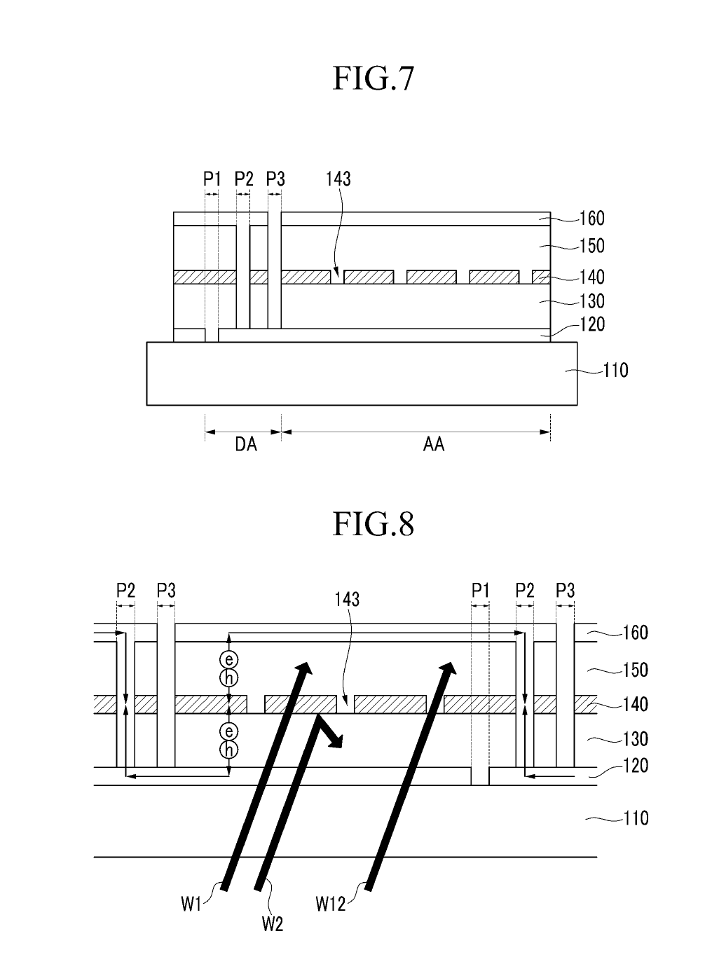

Hereafter, another exemplary embodiment of a unit solar cell manufactured in accordance with the invention will be described with reference to FIGS. 6 and 7.

FIG. 6 is a top plan view of another exemplary embodiment of one unit solar cell of a thin film solar cell, manufactured in accordance with the invention, and FIG. 7 is a cross-sectional view of the unit solar cell of FIG. 6 taken along line VII-VII. What has already been described in the above-described embodiment will not be repeated in the description of the embodiment illustrated in FIGS. 6 and 7.

Referring to FIGS. 6 and 7, each unit solar cell 100 of the thin film solar cell includes an active area AA where solar energy is received and photoelectric current is generated, and a non-active area DA where the plurality of scribe lines P1, P2, and P3 are formed.

The unit solar cell 100 of the illustrated embodiment also includes a first electrode 120, a first active layer 130, an interlayer 140, a second active layer 150, and a second electrode 160, which are disposed on the substrate 110, as in the above-described embodiment.

Also, the active area AA includes a first portion where the interlayer 140 is disposed, and a second portion where the interlayer 140 is not disposed.

Differently from the unit solar cell 100 of the previously described embodiment, the unit solar cell of the illustrated embodiment includes the interlayer 140 of a discontinuous shape in the active area AA. In the plan view of the unit solar cell shown in FIG. 6, an opening in the interlayer 140 is not discrete element, but instead, the interlayer 140 is a discrete element. In other words, the interlayer 140 is formed in an island shape. The active area AA includes a first portion where a plurality of island interlayers 140 are disposed, and a second portion 143 where no island interlayer 140 is disposed. The second (e.g., opening) portion 143 of the interlayer 140 is a unitary continuous member of the unit solar cell.

The first scribe line P1 is longitudinally extended in a first (e.g., vertical) direction, in a plan view of the unit solar cell. The second scribe line P2 and the third scribe line P3 are each longitudinally extended in the first direction, in a plan view of the unit solar cell and are each arranged parallel to the first scribe line P1. Each of the first scribe line P1, the second scribe line P2 and the third scribe line P3 are longitudinally extended an entire dimension of the unit solar cell in the first direction, as illustrated in FIG. 6.

An increase of the light absorption amount by including the first portion and the second portion of the active area AA will be described with reference to FIG. 8.

FIG. 8 is a cross-sectional view schematically showing an exemplary embodiment of travel of incident light and electrical current flow in a unit solar cell, according to the invention.

Referring to FIG. 8, in the active area AA, a first portion (“W1”) of light entering and passing through the substrate 110 completely passes through the island interlayers 140 and is absorbed by the second active layer 150. A second portion (“W2”) of the incident light is reflected by the island interlayers 140 and returns to the first active layer 130. As described above, since the light W2 reflected by the island interlayers 140 is re-absorbed by the first active layer 130, the efficiency of the first active layer 130 may be increased.

Also, since the island interlayers 140 are disposed only in a first portion of the active area AA, a third portion (“W12”) of the light entering and passing through the substrate 110 may completely pass through a second portion 143 where no interlayer 140 is disposed, and reach the second active layer 150, to thereby increase the total amount of light reaching the second active layer 150.

The island interlayers 140 may reduce or effectively prevent an electrical current from flowing abnormally through the island interlayers 140, if scribing is performed as few as three times.

Referring to FIG. 8, the first active layer 130 and the second active layer 150 absorb light individually, to thereby produce electrons (“\textcircled{e}”) and holes (“\textcircled{h}”., The electrons \textcircled{e} and the holes \textcircled{h}. are separated by internal electric fields of the first active layer 130 and the second active layer 150, and move to the first electrode 120 and the second electrode 160, respectively, as shown by the arrows extending from the electron\textcircled{e} and hole\textcircled{h} groups. As illustrated, the electrons \textcircled{e} and the holes \textcircled{h} may move through the second scribe line P2. When the electrons \textcircled{e} and the holes \textcircled{h} move through the second scribe line P2, abnormal flow of electrical current may occur in a portion where the second scribe line P2 contacts the interlayer 140.

In the illustrated embodiment of the invention, since the interlayer 140 are disposed in a discontinuous shape, that is, an island shape, it is possible to reduce of effectively prevent the flow of abnormal electrical current through the island interlayers 140. In turn, electrical current consumption may be decreased and to thereby reduce or effectively prevent deterioration of the efficiency of the thin film solar cell. Also, since it is possible to omit an additional scribing process for removing such abnormal electrical current flow, the overall process becomes simplified.

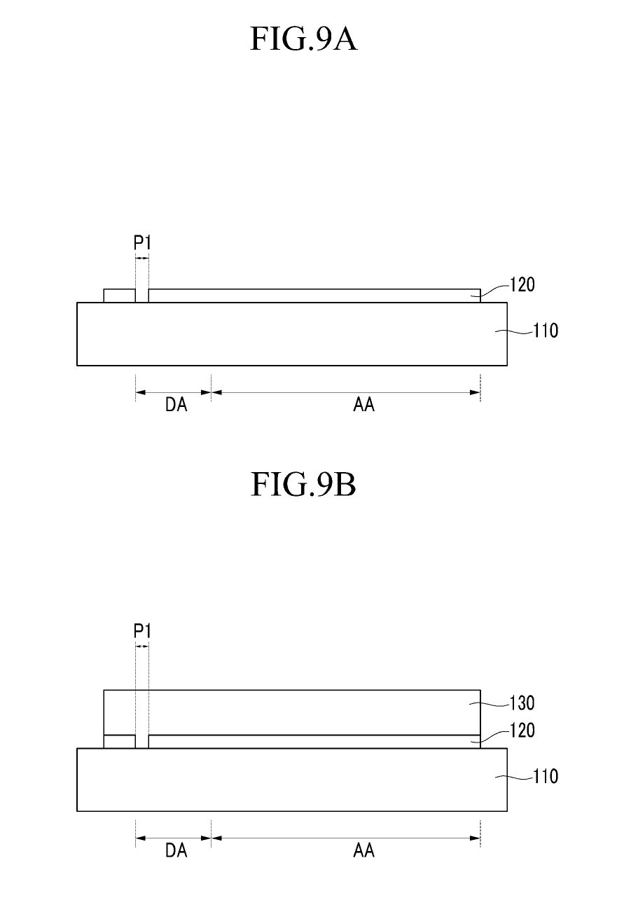

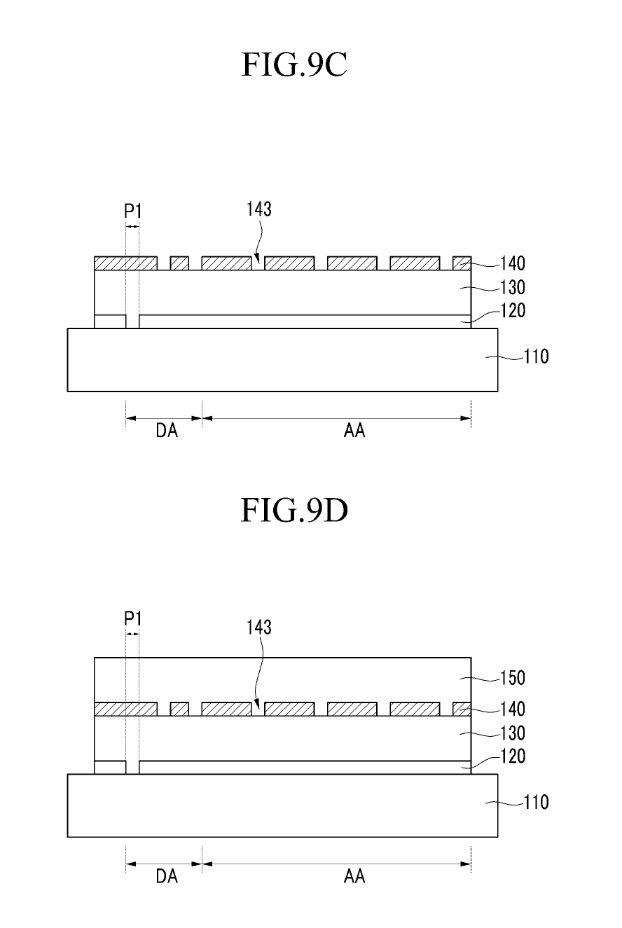

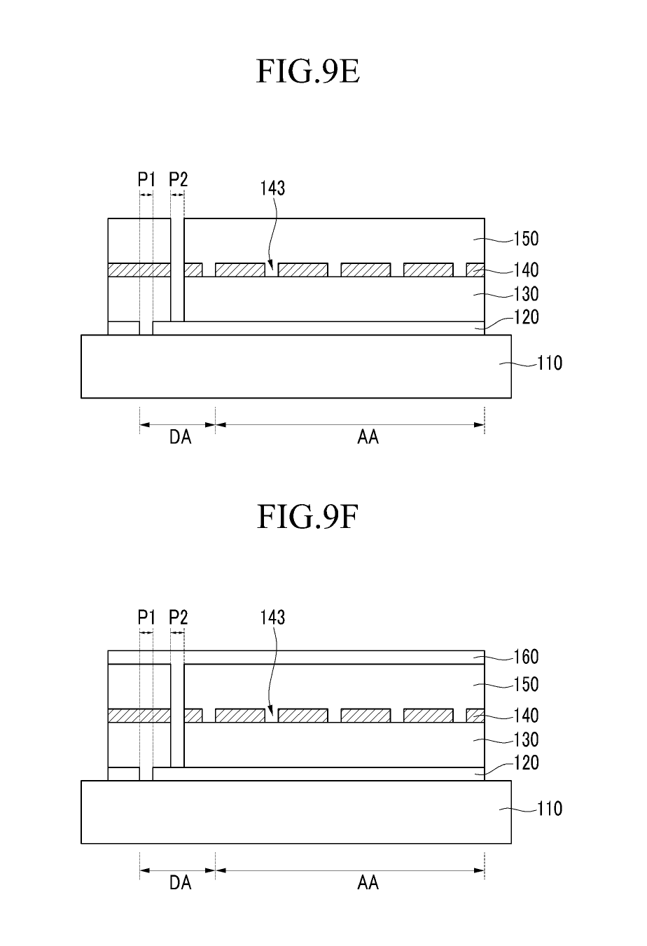

Hereafter, an exemplary embodiment of a method for manufacturing the unit solar cell illustrated in FIGS. 6 and 7 will be described with reference to FIGS. 9A to 9F, along with FIGS. 6 and 7.

FIGS. 9A to 9F are cross-sectional views sequentially showing an exemplary embodiment of a manufacturing process of unit solar cells of FIGS. 6 and 7.

Referring to FIG. 9A, the first electrode 120 is formed directly on the substrate 110, and the first electrode 120 is patterned using a scribing device such as a Nd:YAG laser to thereby form the first scribe line P1 in the non-active area DA.

Referring to FIG. 9B, the first active layer 130 is formed directly on the first electrode 120. The first active layer 130 includes the first impurity doped layer 131, the intrinsic layer 132, and the second impurity doped layer 133, which are sequentially formed through a method such as plasma enhanced chemical vapor deposition (“PECVD”).

Referring to FIG. 9C, the interlayer 140 is formed directly on the first active layer 130. The interlayer 140 may be formed in the shape of islands by using a thin film growth method. Non-limiting examples of the method for forming the island interlayers 140 include sputtering and chemical vapor deposition (“CVD”) methods. The thin film growth method may include nucleation and growing each nucleus in a form of a thin film. Island-shaped thin films may be formed by stopping the deposition before the thin film is formed on an entire surface of the substrate. The forming of the island-shaped interlayer 140, forms the second portion 143 where no interlayer 140 is disposed.

Since the island interlayers 140 are formed using the thin film growth method, a separate patterning process is not required. Thus, the manufacturing process may be simplified and production cost may be reduced.

Referring to FIG. 9D, the second active layer 150 is formed directly on the interlayer 140. The second active layer 150 includes the first impurity doped layer 151, the intrinsic layer 152, and the second impurity doped layer 153, which may be sequentially formed through a method such as a plasma enhanced chemical vapor deposition (“PECVD”).

Referring to FIG. 9E, the second active layer 150, the interlayer 140, and the first active layer 130 are patterned using a scribing device such as a Nd:YAG laser to thereby form the second scribe line P2 in the non-active area DA. The second active layer 150, the interlayer 140, and the first active layer 130 may be simultaneously patterned using the scribing device to thereby form the second scribe line P2 in the non-active area DA.

Referring to FIG. 9F, the second electrode 160 is formed directly on the second active layer 150.

Referring to FIG. 7, the second electrode 160, the second active layer 150, the interlayer 140, and the first active layer 130 are patterned to thereby form the third scribe line P3 in the non-active area DA. The second electrode 160, the second active layer 150, the interlayer 140, and the first active layer 130 may be simultaneously patterned using the scribing device to thereby form the third scribe line P3 in the non-active area DA.

In the above illustrated embodiment, only a tandem solar cell including the first active layer and the second active layer is exemplarily described, but it is obvious to those skilled in the art that the invention is not limited to this, and the invention may be applied in the same way to multi-junction solar cells that include one or more intermediate (e.g., third) active layers between the first active layer and the second active layer. Herein, the above-described interlayer may be disposed between the first active layer and the intermediate active layer, between the second active layer and the intermediate active layer, or between intermediate active layers. When an intermediate active layer is disposed between the first active layer and the second active layer, the intermediate active layer may include an intrinsic layer including a material capable of controlling bandgap. In one exemplary embodiment, the intrinsic layer may include doped amorphous silicon, e.g., amorphous silicon germanium (“a-SiGe”).

Although only an exemplary embodiment of a superstrate-type solar cell, in which light enters through a substrate has been described above, the invention is not limited to the exemplary embodiment, and the invention may be applied in the same way to a substrate-type solar cell as well in which light enters from a side of the structure opposite to the substrate.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film solar cell, comprising
a plurality of a unit solar cell, each including an active area and a non-active area,
wherein each unit solar cell further includes:
a first electrode;
a first active layer disposed on the first electrode;
an interlayer disposed on the first active layer;
a second active layer disposed on the interlayer; and
a second electrode disposed on the second active layer,
wherein the active area of the unit solar cell includes a first portion where the interlayer is disposed, and a second portion where the interlayer is not disposed.

2. The thin film solar cell of claim 1, wherein the interlayer comprises a plurality of a discrete opening disposed in the active area of the unit solar cell.

3. The thin film solar cell of claim 2, wherein the non-active area includes:
a first scribe line penetrating the first electrode, in a first direction perpendicular to the first electrode;
a second scribe line penetrating the first active layer and the interlayer, in the first direction;
a third scribe line penetrating the first active layer, the interlayer, and the second active layer, in the first direction; and
a fourth scribe line penetrating the first active layer, the interlayer, the second active layer, and the second electrode, in the first direction.

4. The thin film solar cell of claim 1, wherein the interlayer is disposed in a shape of a plurality of an island.

5. The thin film solar cell of claim 4, wherein the non-active area includes:
a first scribe line penetrating the first electrode, in a first direction perpendicular to the first electrode;
a second scribe line penetrating the first active layer, the interlayer, and the second active layer, in the first direction; and
a third scribe line penetrating the first active layer, the interlayer, the second active layer, and the second electrode, in the first direction.

6. The thin film solar cell of claim 1, wherein the interlayer includes a selective light transmission material which allows light of first wavelength ranges to be transmitted therethrough, and reflects light of second wavelength ranges different from the first wavelength ranges.

7. The thin film solar cell of claim 6, wherein the selective light transmission material includes at least one selected from the group consisting of a metal oxide, a semi-metal oxide, a semi-metal nitride, and a combination thereof.

8. The thin film solar cell of claim 7, wherein the selective light transmission material includes at least one selected from the group consisting of zinc oxide, tungsten oxide, silicon oxide, silicon nitride, and a combination thereof.

9. The thin film solar cell of claim 1, wherein the first active layer and the second active layer respectively absorb light of different wavelength ranges.

10. The thin film solar cell of claim 9, wherein
the first active layer includes amorphous silicon, and
the second active layer includes at least one selected from the group consisting of amorphous silicon, doped amorphous silicon, nanocrystalline silicon, microcrystalline silicon, and a combination thereof.

11. The thin film solar cell of claim 1, further comprising a third active layer disposed between one of
the first active layer and the interlayer,
the second active layer and the interlayer, and
the first active layer and the interlayer, and the second active layer and the interlayer,
wherein the third active layer includes doped amorphous silicon.

12. A method for manufacturing a thin film solar cell including a plurality of a unit solar cell each including an active area and a non-active area, the method comprising:
forming a first electrode on a substrate;
forming a first active layer on the first electrode;
forming an interlayer on the first active layer;
forming a second active layer on the interlayer; and
forming a second electrode on the second active layer,
wherein the interlayer is disposed in a first portion of the active area, and is not disposed in a second portion of the active area.

13. The method of claim 12, wherein the forming an interlayer on the first active layer includes:
disposing the interlayer on the first active layer; and
patterning the interlayer in the active area of the unit solar cell.

14. The method of claim 13, wherein the interlayer is patterned using a laser.

15. The method of claim 13, further comprising:
patterning the first electrode disposed in the non-active area, after the first electrode is formed;
patterning the interlayer and the first active layer disposed in the non-active area, after the interlayer is formed; and
patterning the second active layer, the interlayer, and the first active layer disposed in the non-active area, after the second active layer is formed,
wherein the patterning the interlayer disposed in the active area, is performed during the patterning the interlayer and the first active layer disposed in the non-active area after the interlayer is formed.

16. The method of claim 12, wherein the forming an interlayer comprises
depositing the interlayer on the first active layer, in a shape of islands.

17. The method of claim 16, wherein the interlayer is formed through a thin film growth method.

18. The method of claim 17, wherein the thin film growth method include sputtering and chemical vapor deposition methods.
